(19) United States
(12) Patent Application Publication
(10) Pub. No.: US 2003/0179043 A1
(43) Pub. Date: Sep. 25, 2003

(54) Method and apparatus for providing carrier cancellation in a feed forward amplifier circuit

(76) Inventor: John Matz, Hanover Park, IL (US)

Correspondence Address: MARSHALL, GERSTEIN & BORUN (MOTOROLA), 233 SOUTH WACKER DRIVE, SUITE 6300, CHICAGO, IL, 60606-6402, US

(21) Appl. No.: 10/101,192

(22) Filed: Mar. 19, 2002

(51) Int. Cl. H03F 1/26

(52) U.S. Cl. 330/151

(57) ABSTRACT

A feed forward amplifier network (100) employs a method (300) and apparatus for providing carrier cancellation in a feed forward amplifier circuit (101). A modulator (118, 120) modulates (303) an input signal (141) of the amplifier circuit (101) with a reference modulation based on a reference signal (143, 145) and a control signal (153, 155). The amplifier circuit (101) amplifies (305) the modulated signal, introducing nonlinear distortion in the process. A modulation determination circuit (107, 109, 115) determines (307) the reference modulation in the amplified signal and provides a determined signal to an adjustment circuit (105). A residual modulation detection circuit (139, 125, 127, 129) demodulates (313) the determined modulation to recover any residual modulation remaining in the determined signal and adjusts (317) the control signal (153, 155) to reduce the recovered residual modulation and to produce carrier cancellation in the determined signal.

### FIELD OF THE INVENTION

The present invention relates generally to power amplifier circuits and, in particular, a method and an apparatus for providing carrier cancellation in a feed forward amplifier circuit.

### BACKGROUND OF THE INVENTION

Radio frequency (RF) power amplifiers, such as class AB transistor amplifiers, are known to introduce amplitude and phase distortion in an amplified output signal due to the inherent nonlinear characteristics of the devices. Such distortion typically includes high order nonlinearities (e.g., fifth order, seventh order, and ninth order intermodulation products) when the device is driven with high power input signals, as is the case for base station amplifiers at a typical cellular base site. When transmitted, the distortion creates unwanted interference in the transmission bandwidth of the cellular system—for example, at the frequencies corresponding to the fifth order, seventh order, and ninth order intermodulation products.

To reduce the nonlinear distortion produced by high power RF amplifiers, amplifier designers generally use a linearization technique, such as feed forward. In one feed forward realization, an input signal to an RF amplifier is sampled prior to amplification by the RF amplifier. An RF pilot reference signal is combined with the input signal subsequent to the sampling of the input signal. The input signal and the RF pilot signal are applied to the RF amplifier. The RF amplifier amplifies both signals and introduces nonlinear amplitude and phase distortion into both signals during the amplification process. The amplified signal is sampled and the sampled input signal is subtracted from the sampled amplified signal to extract the distortion in the sampled amplified signal in a process commonly known as carrier cancellation. This extracted distortion is commonly called an error signal.

The error signal is adjusted in amplitude and phase based on the level of the RF pilot signal detected with an RF pilot receiver at the output of the feed forward amplifier network. The adjusted error signal is amplified and subtracted from the originally amplified signal to produce a corrected signal having less distortion than the originally amplified signal. The corrected signal serves as the output signal of the feed forward network. Thus, the feed forward approach reduces the distortion introduced by the high power RF amplifier circuit as indicated by a reduction in the level of the RF pilot signal in the output signal.

Carrier cancellation reduces the power required from the error amplifier. This allows an error amplifier to be relatively small. One method to provide carrier cancellation is to adjust the level of one of the sampled signals that is subtracted from the other to minimize the power in the error signal. Typically, the control of the level in magnitude and phase is accomplished by a microprocessor and at least two digital to analog converters, which increase cost and power consumption. Therefore, a need exists for providing carrier cancellation in a feed forward amplifier circuit without complex and costly circuitry.

### BRIEF DESCRIPTION OF THE DRAWINGS

FIG. 1 illustrates a feed forward amplifier network in accordance with a preferred embodiment of the present invention.

FIG. 2 illustrates a preferred reference signal receiver in accordance with the present invention.

FIG. 3 illustrates a logic flow diagram of steps executed to provide carrier cancellation in a feed forward amplifier circuit in accordance with the present invention.

### DESCRIPTION OF A PREFERRED EMBODIMENTS

Generally, the present invention encompasses a method and an apparatus for providing carrier cancellation in a feed forward amplifier circuit. A modulator modulates an input signal of the amplifier circuit with a reference modulation including a reference signal and a control signal. An amplifier amplifies the modulated signal to produce an amplified signal and introduces nonlinear distortion during the amplification process. A sample of the amplified signal is subtracted from a sample of the input signal to produce an error signal. A sample of the error signal is first amplitude detected to produce a detected error signal, i.e., to recover any portion of the reference signal existing in the sample of the error signal. The detected error signal is then correlated against the reference signal and low-pass filtered. Thus, the output of the low-pass filter becomes a control signal used to optimize the subtraction in the carrier cancellation by controlling the amplitude or phase of one of the inputs to a subtractor. By optimizing carrier cancellation in a feed forward amplifier circuit in this manner, the present invention obviates the need for a power detector in the error amplifier and the associated analog-to-digital converter, microprocessor, software, and digital-to analog converters. Such a modification reduces the cost and complexity of the feed forward amplifier network by replacing those components with cost-effective, low frequency analog elements.

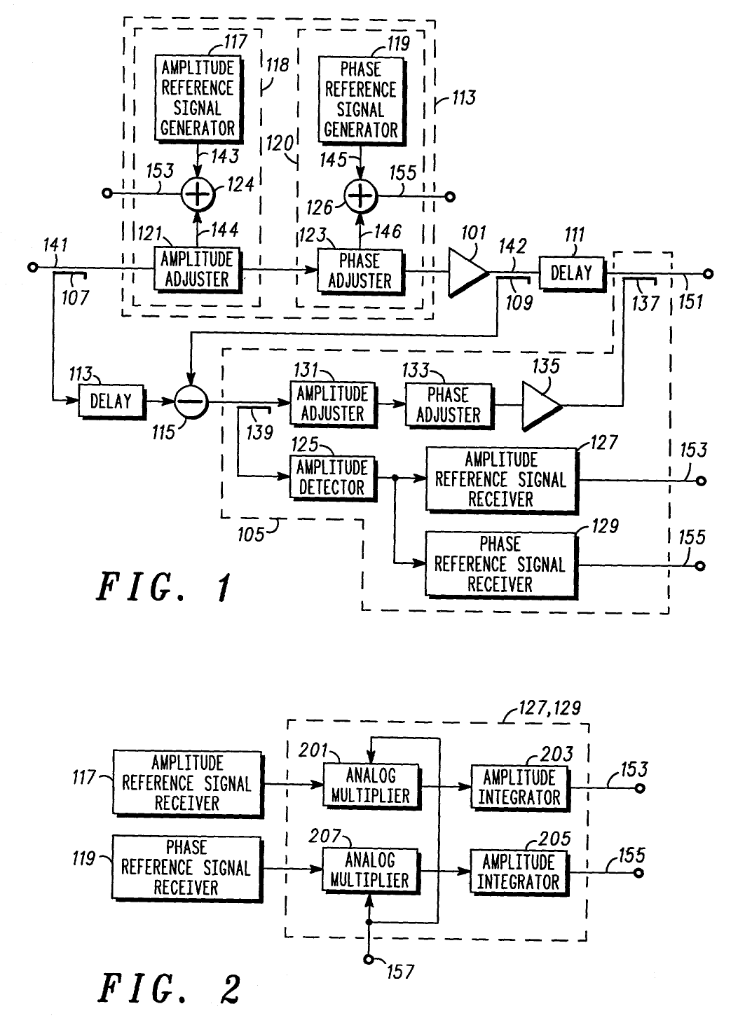

The present invention can be more fully described with reference to FIGS. 1-3. FIG. 1 illustrates a feed forward amplifier network 100 in accordance with a preferred embodiment of the present invention. The feed forward amplifier network 100 comprises an amplifier circuit 101, a modulator 103 for modulating an input signal 141 of the amplifier circuit 101 with a reference modulation based on a control signal, a reducer circuit 105 for reducing any residual reference modulation in an output signal 142 of the amplifier circuit 101, an input coupler 107, an amplifier output coupler 109, two delay devices 111, 113, and a combining network 115. The amplifier circuit 101 may be a class AB, BJT RF power device along with any necessary DC biasing and RF matching circuitry. The coupler 107, 109 may be microstrip or stripline directional couplers. The delay devices 111, 113 may be predetermined length transmission lines, such as coaxial cables, that introduce desired time delays into their respective signal paths. The combining network 115 may be a one-half wavelength transmission line and a directional coupler that together invert and attenuate the signal provided by the amplifier output coupler 109. The modulator 103 and the reducing circuit 105 are discussed in detail below.

In the preferred embodiment, the modulator 103 may be two low frequency modulators 118, 120, each modulator 118, 120 including a reference signal generator 117, 119, an input signal characteristic adjuster 121, 123, and a combining circuit 124, 126. The first modulator 118 modulates the amplitude of the input signal 141, while the second modulator 120 modulates the phase of the input signal 141. In an alternate embodiment, the modulator 103 may be a quadrature amplitude modulator. Although the following discussion describes modulation of both the amplitude and phase of the input signal 141, the discussion is also applicable when the modulator 103 includes only one modulator (e.g., 118 or 120) that modulates either the amplitude or phase of the input signal 141.

The amplitude reference signal generator 117 may be a tone generator that produces a 13 KHz reference amplitude modulation (AM) signal 143, while the phase reference signal generator 119 may be a tone generator that produces an 11 KHz reference phase modulation (PM) signal 145. In an alternate embodiment, the reference signal generators 117, 119 may be pseudonoise (PN) sequence generators that produce digital modulation signals corresponding to orthogonal PN sequences. In yet another embodiment, the reference signal generators 117, 119 might be incorporated into the carrier cancellation control commonly used in a feed forward amplifier network 100. For example, the reference signal generators 117, 119 may be coupled to the combining circuits 124, 126 to produce corrected reference signals in response to control signals as discussed in detail below. The amplitude adjuster 121 preferably comprises a voltage variable attenuator responsive to the reference AM signal 143. Similarly, the phase adjuster 123 may be a known voltage variable phase adjusting circuit (e.g., a circulator and a varactor diode) responsive to the reference PM signal 145.

The reducer circuit 105 preferably comprises an amplitude detector 125, an amplitude reference signal receiver 127, a phase reference signal receiver 129, an amplitude adjuster 131, a phase adjuster 133, an error amplifier 135, and a pair of couplers 137, 139. The amplitude detector 125 may be a well-known envelope detector. The amplitude and phase adjusters 131, 133 are comparable to the input signal amplitude and phase adjusters 121, 123. The error amplifier 135 is similar to the amplifier circuit 101; however, the output power of the error amplifier 135 is considerably less than the output power of the amplifier circuit 101. The couplers 137, 139 may be microstrip or stripline directional couplers. A preferred embodiment of the reference signal receivers 127, 129 is detailed below with regard to FIG. 2.

Operation of the feed forward amplifier network occurs in the following manner in accordance with a preferred embodiment of the present invention. In the low frequency modulator 118, the amplitude reference signal generator 117 provides a reference AM signal 143 to the reference combining circuit 124. In response to the amplitude control signal 153 provided by the amplitude reference signal receiver 127, the reference combining circuit 124 produces a corrected reference AM signal 144 based on the reference AM signal 143. The input signal 141 to the feed forward network 100 is provided to the input signal amplitude adjuster 121 and is also sampled by the input coupler 107. The input signal amplitude adjuster 121 varies the amplitude of the input signal 141 in response to the corrected reference AM signal 144 to impose a reference amplitude modulation on the input signal 141. The amplitude modulated input signal is provided to the input signal phase adjuster 123.

In the low frequency modulator 120, the phase reference signal generator 119 provides a reference PM signal 145 to the reference combining circuit 126. In response to the phase control signal 155 provided by the phase reference signal receiver 129, the reference combining circuit 126 produces a corrected reference PM signal 146 based on the reference PM signal 145. The input signal phase adjuster 123 varies the phase of the input signal 141 in response to the corrected reference PM signal 146 to impose a reference phase modulation on the input signal 141.

The amplitude-and-phase modulated input signal is applied to an input of the amplifier circuit 101. The amplifier circuit 101 amplifies the modulated input signal, introducing nonlinear distortion (e.g., intermodulation distortion) in the process. The amplified signal 142 is sampled by the amplifier output coupler 109 and the sampled amplified signal is supplied as one input to the combining network 115. The other input to the combining network 115 is the time delayed sampled input signal. The time delay introduced to the sampled input signal by the delay device 113 is approximately equal to the time delay introduced to the input signal 141 as the input signal 141 propagated through the input signal amplitude adjuster 121, the input signal phase adjuster 123, the amplifier circuit 101, and the amplifier output coupler 109. Time-delaying the sampled input signal insures that substantially time-coincident input signals are provided to the combining network 115. The couplings provided by the input coupler 107 and the amplifier output coupler 109 are selected to provide substantially equal amplitude input signals to the combining network 115.

The combining network 115 subtracts the sampled input signal from the sampled amplified signal to determine the distortion and modulation contained in the sampled amplified signal. This determined modulation is then supplied to the amplitude adjuster 131. Thus, the input coupler 107, the amplifier output coupler 109, and the combining network 115 together may be a circuit for determining the reference modulation contained in the output signal 142 of the amplifier circuit 101.

The determined modulation is applied to the amplitude adjuster 131, which varies the amplitude of the determined modulation. The amplitude-adjusted modulation is applied to the phase adjuster 133, which varies the phase of the determined modulation. The adjusted modulation (amplitude and phase) is provided to the error amplifier 135. The error amplifier 135 amplifies the adjusted modulation, which includes the distortion, and provides the amplified adjusted modulation to the coupler 137. In a preferred embodiment, a transmission line (not shown) is positioned between the error amplifier 135 and the coupler 137 to invert the amplified adjusted modulation prior to submission to the coupler 137.

The coupler 137 combines the amplified adjusted modulation with the time-delayed amplified signal to effectively subtract the adjusted modulation from the amplified signal 142. The signal resulting from this subtraction is herein referred to as a corrected signal 151. The time delay introduced to the amplified signal 142 by the delay device 111 is approximately equal to the time delay introduced to the sampled amplified signal as the sampled amplified signal propagated through the combining network 115, the amplified adjuster 131, the phase adjuster 133, the error amplifier 135, and the coupler 137. In this embodiment, the amplitude adjuster 131, the phase adjuster 133, the error amplifier 135, and the transmission line between the error amplifier 135 and coupler 137 together form a circuit for adjusting the amplitude and phase of the determined modulation. The coupler 137 provides for combining the adjusted modulation with the delayed output signal from the amplifier circuit 101, such that the adjusted modulation is subtracted from the delayed output signal to produce the corrected signal 151.

Referring back to the combining network 115, the determined modulation is also sampled by the coupler 139 and the sampled determined modulation is provided to the input of the amplitude detector 125. The amplitude detector 125 detects (recovers) the amplitude of any residual modulation remaining in the sampled determined modulation. The combined operations of the coupler 139 and the amplitude detector 125 are generally considered a form of demodulation.

Since two modulations (AM and PM) may be present in the sampled determined modulation, the amplitude detector 125 provides the recovered residual modulation to the phase reference signal receiver 129 and the amplitude reference signal receiver 127. If only one reference modulation is present, the recovered residual modulation need only be supplied to the corresponding reference signal receiver 127, 129. The reference signal receivers 127, 129 produce and adjust their respective control signals 153, 155 based on the corresponding amount of recovered residual modulation. Thus, the coupler 139 and the amplitude detector 125 together provide for recovering residual modulation in the determined modulation, while the reference signal receivers 127, 129 produce and adjust the control signals 153, 155 used by the amplitude modulator 118 and the phase modulator 120.

In a preferred embodiment, the control signals 153, 155 are adjusted to minimize the amount of recovered residual modulation. Since the modulation determined by the combining network 115, and subsequently adjusted by the amplitude adjuster 131, the phase adjuster 133, and the error amplifier 135, includes the distortion produced by the amplifier circuit 101, the net effect of reducing the residual modulation in the corrected signal 151 (i.e., the output signal of the feed forward network 100) is a reduction in the amount of nonlinear distortion in the corrected signal 151. Reduced output signal distortion is a result that all feed forward amplifier network implementations strive to attain.

FIG. 2 illustrates a preferred embodiment 200 of the reference signal receivers 127, 129 of FIG. 1. The amplitude reference signal receiver 127 may be an analog multiplier 201 and an amplitude integrator 203. The phase reference signal receiver 129 may be an analog multiplier 207 and a phase integrator 205. In the preferred embodiment, the amplitude integrator 203 and the phase integrator 205 each may be a very narrowband (e.g., 1 Hz) operational amplifier integrator 203, 205 which are desirable to minimize small offset errors in the control signals 153, 155.

To produce or adjust the control signals 153, 155 provided to the amplitude and phase modulators 118, 120, the analog multipliers 201, 207 accept the recovered residual modulation 157 and correlate (e.g., multiply) the recovered residual modulation 157 with the corresponding reference modulation signals 143, 145 produced by the reference signal generators 117, 119 to obtain respective correlation signals. Each correlation signal is then filtered by the appropriate integrator 203, 205 to produce the updated control signal 153, 155. For example, to adjust the amplitude control signal 153, the analog multiplier 201 correlates the reference AM signal 143 with the recovered residual amplitude modulation 157 to obtain an amplitude correlation signal. The amplitude correlation signal is then filtered by the amplitude integrator 203 to produce the updated amplitude control signal 153. In a similar manner to adjust the phase control signal 155, the analog multiplier 207 correlates the reference PM signal 145 with the recovered residual phase modulation 157 to obtain a phase correlation signal. The phase correlation signal is then filtered by the phase integrator 205 to produce the updated phase control signal 155.

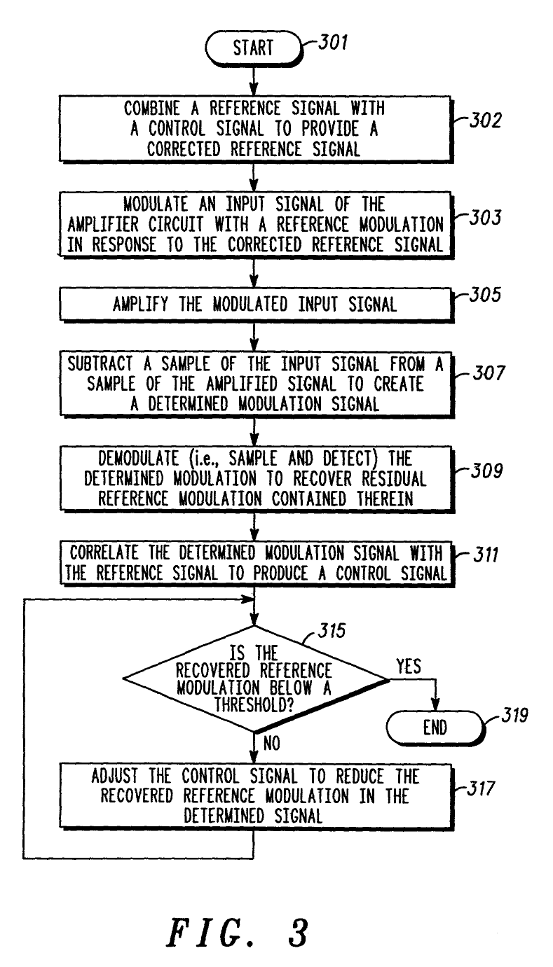

FIG. 3 illustrates a logic flow diagram 300 of steps executed to provide carrier cancellation in a feed forward amplifier circuit in accordance with the present invention. The logic flow begins (301) when a reference signal is combined (302) with a control signal to produce a composite reference signal. An input signal of the amplifier circuit is modulated (303) with a reference modulation in response to the composite reference signal. The reference modulation may be AM, PM, or both and is preferably applied as described above with regard to FIG. 1. The amplifier circuit amplifies (305) the modulated input signal and, due to the inherent nonlinearities present in semiconductor devices, introduces nonlinear distortion during the amplification process.

The reference modulation contained in the amplified signal is then determined (307) by subtracting a sample of the input signal from a sample of the amplified signal to produce a determined signal. The determined modulation (i.e., modulation associated with the determined signal) is demodulated (i.e., sampled and detected) (309) to recover any residual modulation remaining in the determined signal. The determined signal is then correlated (311) with the reference signal to produce a control signal. In a preferred embodiment, when the amount of residual modulation (i.e., recovered reference modulation) exceeds a predetermined threshold (315), the control signal driving a characteristic adjustment (309) of the input signal (i.e., amplitude, phase, or both) is adjusted (317) to reduce the residual modulation, and correspondingly improve the carrier cancellation in the determined signal. Once the residual modulation is below the threshold (315), the logic flow ends (319).

The present invention encompasses a method and apparatus for providing carrier cancellation in a feed forward amplifier circuit. This invention eliminates the need for the complex, costly RF circuitry associated with the generation and reception of RF pilot signals. The present invention utilizes low frequency modulation as the reference signal for providing carrier cancellation at the input to the error amplifier in a feed forward amplifier network. Thus, the present invention permits the use of low cost analog circuitry to generate and detect the reference modulation.

What is claimed:

1. A method for providing carrier cancellation in a feed forward amplifier circuit, the method comprising:
a) modulating an input signal to the amplifier circuit with a reference modulation based on a control signal to produce a modulated signal;
b) amplifying the modulated signal to produce an amplified modulated signal;
c) sampling the input signal to produce a sampled input signal;
d) sampling the amplified modulated signal to produce a sampled amplified modulated signal;
e) subtracting at least a portion of the sampled input signal from at least a portion of the sampled amplified modulated signal to produce a determined modulation;
f) using an amplitude detector to determine the reference modulation contained in the determined modulation to produce the control signal; and
g) using the control signal to adjust carrier cancellation of the feed forward amplifier circuit.

2. The method of claim 1, wherein step (g) comprises:
g1) generating a reference signal;
g2) combining the control signal with the reference signal to produce a corrected reference signal; and
g3) adjusting a characteristic of the input signal in response to the corrected reference signal to produce the reference modulation.

3. The method of claim 2, wherein the characteristic of the input signal comprises one of an amplitude and a phase.

4. The method of claim 1, wherein step (f) comprises:
f1) demodulating the determined modulation to recover a residual modulation contained therein to produce a recovered residual modulation; and
f2) adjusting the control signal based on the recovered residual modulation, such that the residual modulation is reduced in the reference modulation.

5. The method of claim 4, wherein step (f1) comprises:
f1a) sampling the determined modulation to produce a sampled determined modulation; and
f1b) detecting the residual modulation in the sampled determined modulation to produce the recovered residual modulation.

6. The method of claim 4, wherein step (f2) comprises:
f2a) multiplying the reference modulation with the recovered residual modulation to produce a correlation signal; and
f2b) filtering the correlation signal to obtain the control signal.

7. The method of claim 1, wherein the reference modulation comprises one of amplitude modulation and phase modulation.

8. A method for providing carrier cancellation in a feed forward amplifier circuit, the method comprising:
a) generating a reference signal;
b) combining the control signal with the reference signal to produce a corrected reference signal;
c) adjusting a characteristic of the input signal in response to the corrected reference signal to produce a reference modulation;
d) modulating an input signal to the amplifier circuit with the reference modulation to produce a modulated signal;
e) amplifying the modulated signal to produce an amplified modulated signal;
f) determining the reference modulation contained in the amplified modulated signal to produce a determined modulation;
g) demodulating the determined modulation to recover a residual modulation contained therein to produce a recovered residual modulation; and
h) adjusting the control signal based on the recovered residual modulation, such that the residual modulation is reduced in the amplified modulated signal.

9. The method of claim 8, wherein the characteristic of the input signal comprises one of an amplitude and a phase.

10. The method of claim 8, wherein step (f) comprises:
f1) multiplying the reference modulation with the recovered residual modulation to produce a correlation signal; and
f2) filtering the correlation signal to obtain the control signal.

11. A feed forward amplifier network comprising:
an amplifier circuit having an input responsive to an input signal and an output producing an output signal;
a first coupler sampling the input signal to produce a sampled input signal;
a second coupler sampling the output signal to produce a sampled output signal;
a modulation device coupled to the input of the amplifier circuit, the modulation device modulating the input signal with a reference modulation based on a control signal;
a first combination circuit responsive to the sampled output signal, and the sampled input signal and producing a determined modulation by subtracting the sampled input signal and from the sampled output signal;
an amplitude detector responsive to the determined modulation to produce a control signal; and
a reducer circuit adapted to adjust carrier cancellation from the amplifier circuit based on the control signal.

12. The feed forward amplifier network of claim 11, wherein the reducing circuit comprises:
a first adjustment circuit operably coupled to the first combination circuit, the first adjustment circuit being adapted to adjust a characteristic of the determined modulation to produce an adjusted modulation;
a second combination circuit operably coupled to the output of the amplifier circuit and the first adjustment circuit, the second combination circuit being adapted to combine the adjusted modulation with the output signal of the amplifier circuit to produce a corrected signal;
a residual modulation detection circuit operably coupled to the output of the first combination circuit, the residual modulation detection circuit being adapted to recover a residual modulation contained in the determined modulation to produce a recovered residual modulation; and
a second adjustment circuit coupled to the residual modulation detection circuit and the modulation device, the second adjustment circuit being adapted to adjust the control signal based on the recovered residual modulation.

13. The feed forward amplifier network of claim 12, wherein the adjustment circuit comprises:
a characteristic adjuster; and
a second amplifier circuit, coupled to an output of the characteristic adjuster.

14. The feed forward amplifier network of claim 13, wherein the characteristic adjuster comprises one of an amplitude adjuster and a phase adjuster.

15. The feed forward amplifier network of claim 12, further comprising:
a coupler that samples the determined modulation to produce a sampled determined modulation; and
an amplitude detector, coupled to the coupler, that extracts an amplitude of the residual modulation from the determined modulation to produce the recovered residual modulation.

16. The feed forward amplifier network of claim 15, wherein the modulation device comprises:
a reference signal generator that generates a reference signal;
a reference combination circuit responsive to the reference signal and the control signal and producing a corrected reference signal; and
a characteristic adjuster, coupled to the reference combination circuit, that modulates the input signal in response to the corrected reference signal.

17. The feed forward amplifier network of claim 16, wherein the second adjustment circuit comprises a reference signal receiver, coupled to an output of the amplitude detector.

18. The feed forward amplifier network of claim 17, wherein the reference signal receiver comprises:
an analog multiplier that multiplies the reference modulation with the recovered residual modulation to produce a correlated signal; and
an integrator, coupled to the analog multiplier, that filters the correlation signal to produce the control signal.

19. The feed forward multiplier network of claim 11, wherein the modulation device comprises one of an amplitude modulator and a phase modulator.

20. The feed forward amplifier network of claim 11, wherein the first combination circuit comprises a combining network, operably coupled to the first coupler and the second coupler.

21. A feed forward amplifier network comprising:
an amplifier circuit;
a modulator, coupled to an input of the amplifier circuit, that modulates an input signal of the amplifier circuit with a reference modulation based on a control signal;
a modulation determination circuit, coupled to an output of the amplifier circuit, that determines the reference modulation contained in an output signal of the amplifier circuit to produce a determined modulation;
an adjustment circuit, coupled to the modulation determination circuit and the output of the amplifier circuit, that adjusts a characteristic of the determined modulation to produce an adjusted modulation, and combines the adjusted modulation with the output signal of the amplifier circuit to produce a corrected signal; and
a residual modulation detection circuit, coupled to the modulation determination circuit, that recovers a residual modulation contained in the determined modulation and produces the control signal based on the residual modulation.

22. A feed forward amplifier network comprising:
an amplifier circuit;
a reference signal generator that generates a reference signal;
a reference combination circuit coupled to the reference signal generator, that produces a corrected reference signal based on a control signal;
an input signal characteristic adjuster, coupled to the reference combination circuit and an input of the amplifier circuit, that modulates an input signal of the amplifier circuit with a reference modulation based on the corrected reference signal;
a modulation determination circuit, coupled to an output of the amplifier circuit, that determines the reference modulation contained in an output signal of the amplifier circuit, that adjusts a characteristic of the determined modulation to produce an adjusted modulation;
a first coupler, coupled to an output of the adjustment circuit and the output of the amplifier circuit, that combines the adjusted modulation with the output signal of the amplifier circuit to produce a corrected signal;
a second coupler, coupled to the modulation determination circuit, that samples the determined modulation to produce a sampled determined modulation;
an amplitude detector, coupled to the second coupler, that detects an amplitude of a residual modulation contained in the sampled determined modulation to produce a recovered residual modulation; and
a reference signal receiver, coupled to an output of the amplitude detector and the reference combination circuit, that produces the control signal based on the recovered residual modulation.
